(19) United States
(12) Patent Application Publication
(10) Pub. No.: US 2026/0328085 A1
(43) Pub. Date: Oct. 22, 2026

(54) METHODS AND SYSTEMS FOR ESTIMATING PORE THROAT DISTRIBUTION IN POROUS MEDIA

(71) Applicant: BP Corporation North America Inc., Houston, TX (US)

(72) Inventors: Jeremy T. First, Houston, TX (US); Nathan Lane, Katy, TX (US); Abdulla Kerimov, Katy, TX (US)

(73) Assignee: BP Corporation North America Inc., Houston, TX (US)

(21) Appl. No.: 19/654,595

(22) Filed: Apr. 22, 2026

Related U.S. Application Data
(60) Provisional application No. 63/792,452, filed on Apr. 22, 2025.

(51) Int. Cl. E21B 47/002; G06T 7/62; G06T 15/08

(52) U.S. Cl. CPC E21B 47/002; G06T 7/62; G06T 15/08

(57) ABSTRACT

A computer-implemented method for estimating pore throat distribution within a subterranean formation includes receiving a digital image of a rock from the subterranean formation, segmenting the digital image into a plurality of voxels including a plurality of solid voxels each associated with a solid phase mineral of the subterranean formation and a plurality of void voxels each associated with a pore space of the subterranean formation, simulating fluid flow through the plurality of void voxels to identify one or more streamlines through a flowfield of the digital image, applying a geometric transform to the digital image to generate a geometric model of the digital image that maps pore space throughout the digital image, and integrating the one or more streamlines with the geometric model to identify a minimum pore size for each of the one or more streamlines.

### CROSS-REFERENCE TO RELATED APPLICATIONS

This application is a nonprovisional patent application which claims benefit of U.S. provisional patent application No. 63/792,452 filed Apr. 22, 2025, entitled “Methods and Systems for Estimating Pore Throat Distribution in Porous Media”, which is hereby incorporated herein in its entirety for all purposes.

### STATEMENT REGARDING FEDERALLY SPONSORED RESEARCH OR DEVELOPMENT

Not applicable.

### BACKGROUND

In various applications, it may be desired to understand and estimate the pore throat distribution within a porous media. Such estimates depend on the specific properties of the porous media, and the characteristics of fluid(s) flowing through the porous media can influence how particles move through the pore throats. As an example, in hydrocarbon exploration and production, the porous media may comprise an earthen subterranean formation (or more simply “subterranean formations” or “formations”).

To control the invasion of sand and other particles into a wellbore drilled into the subterranean formation, sand control devices like filters (i.e. screens, mesh, proppant) may be used to retain particles larger than a certain diameter while allowing fluids to pass. Pore throat distribution refers to the variation in size, shape, and connectivity of pores throats within the subterranean formation. It controls the movement of fluids, such as oil, gas, and water through the subterranean formation and is thus important for designing filters that prevent fines and particulate migration, while maintaining optimal fluid flow, minimizing fluid loss, protecting downhole equipment, and optimizing well performance. Accurately characterizing the pore throat distribution within a subterranean formation is vital for understanding fluid flow, predicting permeability, and optimizing overall production efficiency of hydrocarbons.

### BRIEF SUMMARY OF THE DISCLOSURE

Methods and systems for estimating pore throat distribution within a subterranean formation are disclosed herein. In an embodiment, a computer-implemented method for estimating pore throat distribution within a subterranean formation comprises (a) receiving a digital image of a rock from the subterranean formation; (b) segmenting the digital image into a plurality of voxels including a plurality of solid voxels each associated with a solid phase mineral of the subterranean formation and a plurality of void voxels each associated with a pore space of the subterranean formation; (c) simulating fluid flow through the plurality of void voxels to identify one or more streamlines through a flowfield of the digital image; (d) applying a geometric transform to the digital image to generate a geometric model of the digital image that maps pore space throughout the digital image; and (e) integrating the one or more streamlines with the geometric model to identify a minimum pore size for each of the one or more streamlines. In some embodiments, the method further comprises (f) generating a pore throat distribution within the digital image based on the minimum pore size for each of the one or more streamlines. In certain embodiments, (d) comprises transforming the segmented digital image to generate an enhanced image identifying one or more features of the digital image. In other embodiments, the one or more features of the digital image comprises a size and/or shape of pores and pore throats in the segmented digital image. In some embodiments, (d) further comprises generating a distance map representing the solid voxels and void voxels by determining a distance from each void voxel to a nearest solid voxel in the digital image. In certain embodiments, (d) further comprises determining distances between the plurality of void voxels to generate the distance map. In other embodiments, (c) comprises identifying the one or more streamlines through the digital image by tracing flowpaths from an inlet to an outlet of the digital image and from the outlet to the inlet, and determining a minimum diameter along each of the one or more flowpaths to obtain pore throat sizes in the digital image. In some embodiments, the pore throat sizes comprise restricting pore throat sizes in the one or more flowpaths.

In an embodiment, a computer-implemented method for estimating pore throat distribution within a subterranean formation comprises (a) receiving a digital image of rock from the subterranean formation; (b) segmenting the digital image into a plurality of voxels including a plurality of solid voxels each associated with a solid phase mineral of the subterranean formation and a plurality of void voxels each associated with a pore space of the subterranean formation; (c) applying a geometric transform to the digital image to generate a geometric model of the digital image that identifies pore space distribution within the digital image; (d) Identifying one or more streamlines through a flow field of the digital image; (e) filtering for accessible volume through the digital image based on the one or more streamlines through the digital image and the geometric model; and (f) generating a pore throat distribution within the digital image based on the accessible volume. In some embodiments, the method further comprises (g) integrating the one or more streamlines with the geometric model to identify a minimum pore throat size for each of the one or more streamlines. In certain embodiments, (c) comprises transforming the segmented digital image to generate an enhanced image identifying one or more features of the digital image. In other embodiments, the one or more features of the digital image comprises a size and/or shape of pores and pore throats in the segmented digital image. In some embodiments, (c) further comprises generating a distance map representing the solid voxels and void voxels by determining a distance from each void voxel to a nearest solid voxel in the digital image. In certain embodiments, the method (c) further comprises determining distances between the plurality of void voxels to generate the distance map. In other embodiments, (d) comprises identifying the one or more streamlines through the digital image by tracing flowpaths from an inlet to an outlet of the digital image and from the outlet to the inlet, and determining a minimum diameter along each of the one or more flowpaths to obtain pore throat sizes in the digital image.

In an embodiment, a system for estimating pore throat distribution within a subterranean formation comprises a processor; and a memory coupled to the processor, wherein machine-readable instructions are stored in the memory, and wherein the machine-readable instructions, when executed on the processor, configure the processor to (a) receive a digital image of rock from the subterranean formation; (b) segment the digital image into a plurality of voxels including a plurality of solid voxels each associated with a solid phase mineral of the subterranean formation and a plurality of void voxels each associated with a pore space of the subterranean formation; (c) simulate fluid flow through the plurality of void voxels to identify one or more streamlines through a flow field of the digital image; (d) apply a geometric transform to the digital image to generate a geometric model of the digital image that maps pore space throughout the digital image; and (e) integrate the one or more streamlines with the geometric model to identify a minimum pore size for each of the one or more streamlines. In some embodiments, the machine-readable instructions, when executed on the processor, further configure the processor to (f) generate a pore throat distribution of the digital image based on the minimum pore size for each of the one or more streamlines. In certain embodiments, the machine-readable instructions, when executed on the processor, further configure the processor to (d1) transform the segmented digital image to generate an enhanced image identifying one or more features of the digital image. In other embodiments, the one or more features of the digital image comprises a size and/or shape of pores and pore throats in the segmented digital image. In some embodiments, the machine-readable instructions, when executed on the processor, further configure the processor to (d) generate a distance map representing the solid voxels and void voxels by determining a distance from each void voxel to a nearest solid voxel in the digital image. In certain embodiments, the machine-readable instructions, when executed on the processor, further configure the processor to determine distances between the plurality of void voxels to generate the distance map. In other embodiments, the machine-readable instructions, when executed on the processor, further configure the processor to identify the one or more streamlines through the digital image by tracing flowpaths from an inlet to an outlet of the digital image and from the outlet to the inlet, and determine a minimum diameter along each of the one or more flowpaths to obtain pore throat sizes in the digital image.

Embodiments described herein comprise a combination of features and characteristics intended to address various shortcomings associated with certain prior devices, systems, and methods. The foregoing has outlined rather broadly the features and technical characteristics of the disclosed embodiments in order that the detailed description that follows may be better understood. The various characteristics and features described above, as well as others, will be readily apparent to those skilled in the art upon reading the following detailed description, and by referring to the accompanying drawings. It should be appreciated that the conception and the specific embodiments disclosed may be readily utilized as a basis for modifying or designing other structures for carrying out the same purposes as the disclosed embodiments. It should also be realized that such equivalent constructions do not depart from the spirit and scope of the principles disclosed herein.

### BRIEF DESCRIPTION OF THE DRAWINGS

For a detailed description of various exemplary embodiments, reference will now be made to the accompanying drawings in which:

FIG. 1 is a schematic view of an exemplary production system for producing formation fluids from a wellbore according to some embodiments;

FIG. 2 is a block diagram of a method for estimating pore throat distribution in a porous media according to some embodiments;

FIG. 3 is a schematic view of exemplary onshore and offshore sources of rock samples and fluid sampling for analysis by embodiments of testing systems and methods according to some embodiments;

FIG. 4 is a schematic view of an embodiment of a testing system for analyzing rock samples according to some embodiments;

FIG. 5 is a schematic representation of two-dimensional (2D) slices and three-dimensional (3D) views of a digital image of a rock sample according to some embodiments, including a tomograph, a segmented image, and a mineral-mapped image according to some embodiments;

FIG. 6 is a schematic representation illustrating three-dimensional (3D) views of exemplary processes performed using the method of FIG. 2 according to some embodiments;

FIG. 7 is a graphical representation illustrating a comparison of the pore throat distribution of a porous media using geometric analysis of a digital image of the porous media with the pore throat distribution of the same porous media using the method of FIG. 2 according to some embodiments;

FIG. 8 is a block diagram of another method for estimating pore throat distribution in a porous media according to some embodiments;

FIG. 9 is a schematic representation illustrating three-dimensional (3D) views of exemplary processes performed using the method of FIG. 8 according to some embodiments;

FIG. 10 is a graphical representation illustrating a comparison of the pore throat distribution of a porous media using geometric analysis of a digital image of the porous media with the pore throat distribution of the same porous media using the method of FIG. 8 according to some embodiments; and

FIG. 11 is a block diagram of an embodiment of a computer system according to some embodiments.

### DETAILED DESCRIPTION

The following discussion is directed to various exemplary embodiments. However, one skilled in the art will understand that the examples disclosed herein have broad application, and that the discussion of any embodiment is meant only to be exemplary of that embodiment and not intended to suggest that the scope of the disclosure, including the claims, is limited to that embodiment.

Certain terms are used throughout the following description and claims to refer to features or components. As one skilled in the art will appreciate, different persons may refer to the same feature or component by different names. This document does not intend to distinguish between components or features that differ in name but not function. The drawing figures are not necessarily to scale. Certain features and components herein may be shown exaggerated in scale or in somewhat schematic form, and some details of conventional elements may not be shown in the interest of clarity and conciseness.

Unless the context dictates the contrary, all ranges set forth herein should be interpreted as being inclusive of their endpoints, and open-ended ranges should be interpreted to include only commercially practical values. Similarly, all lists of values should be considered as inclusive of intermediate values unless the context indicates the contrary.

In the following discussion and in the claims, the terms “including” and “comprising” are used in an open-ended fashion, and thus should be interpreted to mean “including, but not limited to . . . ” Also, the term “couple” or “couples” is intended to mean either an indirect or direct connection. Thus, if a first device couples to a second device, that connection may be through a direct connection, or through an indirect connection via other devices, components, and connections. In addition, as used herein, the terms “axial” and “axially” generally mean along or parallel to a central axis (e.g., central axis of a body or a port), while the terms “radial” and “radially” generally mean perpendicular to the central axis. For instance, an axial distance refers to a distance measured along or parallel to the central axis, and a radial distance means a distance measured perpendicular to the central axis.

As previously described, the pore size distribution within a porous media may depend on specific properties of the porous media, and how efficiently fluid moves through the pore throats may be influenced by the characteristics of the fluids flowing through the porous media. When the porous media comprises a subterranean formation (e.g., such as in the context of hydrocarbon exploration and production), the properties and behavior of a subterranean formation may be directly measured via samples obtained from the formation itself (e.g., in the form of core samples, drill cuttings). However, due to the cost and time required to directly measure petrophysical properties of formation samples (also referred to herein as “rock samples”), the technique of “direct numerical simulation” and/or geometric modeling may be applied to predict or estimate physical properties of the subterranean formation, such as pore throat distribution, porosity, absolute permeability, relative permeability, formation factor, elastic moduli, and the like of rock samples, including samples from different formation types such as consolidated and unconsolidated formations.

In this approach, a three-dimensional (3D) tomographic image of the rock sample is obtained, for example, by way of a computer tomographic (CT) scan. The 3D image may be segmented into a plurality of distinct volume elements or “voxels” (e.g., by “thresholding” their brightness values or by another approach) to distinguish rock matrix from void space. Direct numerical simulation of fluid flow or other physical behavior such as elasticity or electrical conductivity may then be performed, from which porosity, permeability, elastic properties, electrical properties, and the like can be derived. A variety of numerical methods may be applied to solve or approximate the physical equations simulating the appropriate behavior of the rock sample. These methods include, for example, lattice-Boltzmann (LB), finite element, finite difference, finite volume, and the like.

Additionally, estimates of the pore throat distribution in a subterranean formation may be relevant for hydrocarbon production operations, for example designing filters that prevent sand/fines/particulates from flowing into the production system such as in unconsolidated formations and/or open hole completions. In this instance, an overly restrictive filter may inhibit fluid flow through the subterranean formation, requiring increased pressure to be applied to the well. This increased pressure in the near wellbore region can strain completion equipment, initiate negative complex fluid effects (i.e., gas breakout, condensate banking, asphaltene precipitation), and demand more energy to maintain fluid flow, ultimately driving up operational costs. Conversely, an overly permissive filter risks sand/fines/particulates flowing into the wellbore, clogging pipes, damaging production equipment, and generally increasing the cost of operations.

Conventionally, pore throat distributions are estimated based on geometric analysis of the 3D tomographic images obtained from micro-computed tomography (μCT) scans of samples (e.g., core samples) obtained from a subterranean formation. Geometric analysis of 3D images obtained from μCT scans may involve scanning a formation sample to obtain high-resolution 3D images, segmenting the pore space to distinguish between solid phase space (formation rock) and the pore spaces (voids), and generating a geometric model of the pore distribution in the 3D image whereby the connected voids within the sample representing the pores and pore throats are identified that form theoretical fluid flow paths. As used herein, the term “geometric model” of a digital image refers to an abstract representation or map of the pore structure or distribution within porous media derived from a 3D tomographic image. The geometric model may approximate (e.g., utilizing predefined geometric elements or shapes) the complex, irregular shapes of pores formed in the porous media using geometric primitives or shapes to capture essential features such as pore size, shape, and spatial distribution. For instance, a geometric transform may be applied to the 3D image to thereby generate the geometric model thereof. Based on the geometric model of the 3D image, the size, shape, and connectivity of the pores and pore throats of the 3D image may be estimated. As used herein, the term “geometric transform” refers to a mathematical operation that converts a 3D tomographic image of porous media into a new representation or model by altering how spatial information is expressed in the model.

In some instances, the geometric transform applied to the 3D tomographic image to generate the geometric model thereof comprises a Euclidean Distance Transform (EDT) that is applied after segmenting the 3D image to help identify and characterize the pore throats by calculating the distance from each pore space voxel to the nearest solid voxel. Generally, the EDT (e.g., an EDT 3D image or simply EDT image) of a 3D tomographic image provides a map indicating, at each point in the pore space, how far that point is from the nearest “solid” or rock boundary. This distance may be determined using the shortest straight-line or Euclidean distance. In other words, each voxel of the EDT image is assigned a number describing how deep the voxel is within a given pore where areas with higher numbers are further from solid boundaries indicating wider pore spaces.

Following the generation of an EDT image by applying a geometric transform (e.g., EDT in this example), a geometric model of the original 3D tomographic image may be obtained from the EDT image quantifying the pore distribution estimated from the 3D tomographic image. For instance, the geometric model may comprise a maximum inscribed spheres (MIS) model or image that identifies the best places within the 3D tomographic image to “fit” the largest possible spheres inside the pores thereof to estimate the size of the corresponding pores. For instance, local maximums may be identified in the EDT image where the distance to the solid boundary is greater than in surrounding areas where such local maximums may act as centers for the inscribed spheres of the MIS image. In this example, each sphere is centered at a local maximum having a radius equal to the Euclidian distance at that location. The sphere may correspond to the largest sphere that may fit within the given pore without crossing the nearest solid boundary.

While geometric modeling such as MIS images described above may be used to estimate pore sizes and pore distributions of porous media, there is a continuing need for improvements in such models, and particularly for models that capture or account for the “restricting pore throat size” a grain would encounter as it moves through a porous media along a flowpath extending continuously therethrough. As used herein, “restricting pore throat size” refers to the size of the smallest passageway or “throat” that connects larger pores within a porous media along a continuous flowpath extending through the porous media. Particularly, while geometric models may map an estimated pore distribution of a 3D tomographic image, they do not identify the different continuous flowpaths extending through the 3D tomographic image and thus cannot identify the pore throat sizes for the different continuous flowpaths. Due to not identifying the continuous flowpaths, the pore distribution estimated using existing geometric techniques (e.g., EDT and MIS techniques) may include pores that are inaccessible for fluid/particle flow because of, for example, the complex flow patterns (e.g., multiphase flow, anisotropic flow) in the porous media, compaction, and so on. Understanding the size and distribution of these restricting pore throats is necessary for accurately predicting fluid and particle transport within the porous media. For example, in hydrocarbon production, knowing the restricting pore throat size and thus, the natural ability of the formation rock to filter out certain sizes of particles around the wellbore, allow engineers to optimize the completion design, including the size and design of filters, to ensure the filter captures particles that are not otherwise filtered out by the formation itself.

Accordingly, embodiments disclosed herein include methods and systems for estimating pore throat distributions in a porous media that includes integrating geometric analysis of the digital image of a porous media with streamlines through the digital image to thereby capture or account for the restricting pore throat size a grain would encounter as it moves through the porous media. Embodiments of methods and systems for estimating pore throat distributions in a porous media disclosed herein includes segmenting the digital image of a porous media into a plurality of solid phase voxels and pore space or void voxels, generating a geometric model of the digital image that maps pore space throughout the digital image, simulating fluid flow through the plurality of void voxels to identify one or more streamlines by tracing the restricting pore throats along valid flow paths through the porous media, and combining the geometric model of the digital image with the streamlines to identify a minimum pore size for each of the streamlines and generate a pore throat distribution based on the min pore size. In this manner, the maximum size of particle that will be trapped in the porous media may be determined and used in designing a filtration system. Embodiments of methods and systems for estimating pore throat distributions in a porous media disclosed herein further includes filtering for accessible volume through the digital image based on the one or more streamlines through the digital image and the geometric model and generating a pore throat distribution based on the accessible volume.

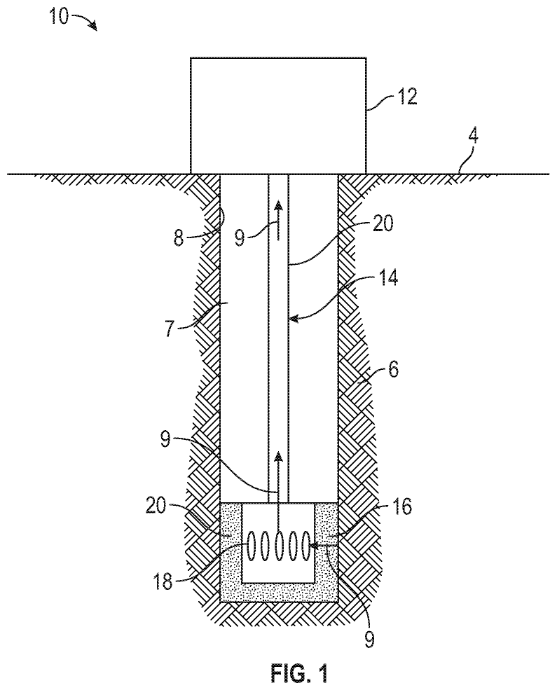

Referring initially to FIG. 1, a production system 10 for producing formation fluids from a wellbore 7 extending into a subterranean formation 6 from the surface 4 is shown. In this exemplary embodiment, production system 10 generally includes a pumping assembly 12, a production string 14, an inlet sub 16, and a downhole filter 20. Pumping assembly 12 is positioned on or at the surface 4, and production string 14 (e.g., a string of production tubing) is coupled to and extends from the pumping assembly 12 into the wellbore 7. Particularly, the production string 14 includes a first or upper end positioned at or near the surface 4 coupled to pumping assembly 12, and an opposing second or lower end coupled to inlet sub 16. In some embodiments, a portion of the pumping assembly 12 may also be located in the wellbore 7 along the production string 14.

Production string 14 may comprise any suitable elongate tubular member or assembly. For instance, in some embodiments, production string 14 may comprise a plurality of tubular members (e.g., pipes) coupled end-to-end. In some embodiments, production string 14 may comprise a reel-able conduit such as coiled tubing and the like. Additionally, the pumping assembly 12 may comprise a beam pump, horsehead pump, or any other suitable pumping assembly. During operations, the pumping assembly 12 may draw formation fluids 9 out of the wellbore 7 via the inlet sub 16 and production string 14.

The inlet sub 16 is suspended in the wellbore 7 from the lower end of production string 14. Inlet sub 16 comprises one or more inlet ports 18 through which formation fluids 9 may be communicated to the production string 14. Additionally, the downhole filter 20 is located in the wellbore 7 between a sidewall 8 of the wellbore 7 and the inlet ports 18 of inlet sub 16. Downhole filter 20 is configured to filter particulates from the formation fluids 9 prior to entering the inlet sub 16. During operations, formation fluids 9 may flow through the downhole filter 20 and be drawn into the inlet sub 16 via inlet ports 18, and then through the production string 14 to the surface 4 via the pumping assembly 12. However, particulates entrained within the formation fluids 9 flowing from formation 6 may be filtered from the formation fluids 9 as the formation fluids 9 flow throw the downhole filter 20 and prior to entering the inlet sub 16.

In some embodiments, downhole filter 20 comprises packed sand (e.g., a sand screen) and/or other permeable filters having a grain size distribution or permeability configured to filter the particulates from the formation fluids 9. The permeability of downhole filter 20 may be based on properties of the surrounding formation 6 including those properties that influence the amount and type of particulates that are entrained in the formation fluids 9. Particularly, it is generally desirable to have the downhole filter 20 as permeable as allowable by the properties of the formation 6 (e.g., without also allowing particulates entrained in the formation fluids 9 to penetrate through the downhole filter 20) to minimize the amount of pressure that must be applied by pumping assembly 12 to continuously draw formation fluids 9 from the formation 6.

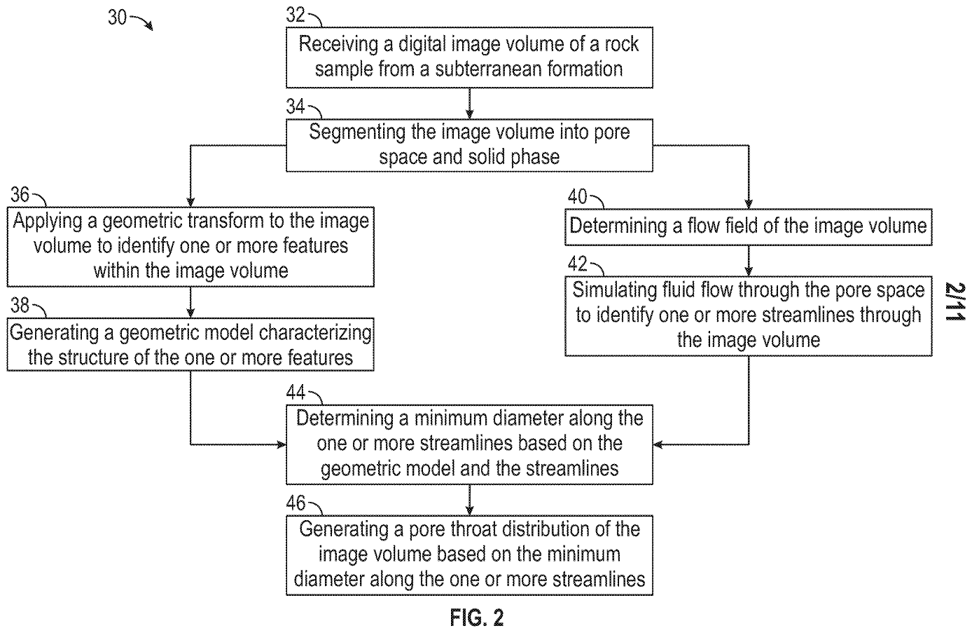

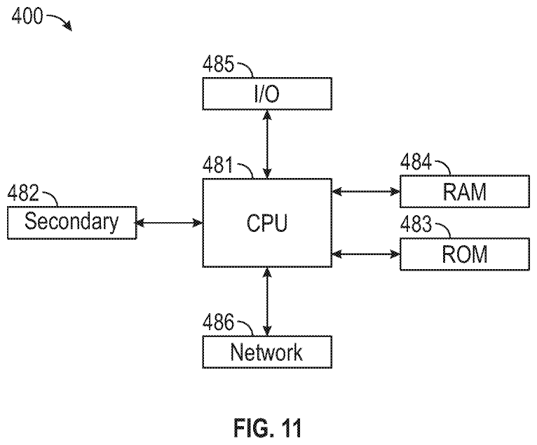

Referring to FIG. 2, a method 30 for estimating pore throat distribution in a porous media according to some embodiments is shown. In this exemplary embodiment, one or more features of method 30 may be performed by, with, or using a computer system or device (or multiple computer devices). The computer device (or devices) may comprise or be similar to the example computer system 400 shown in FIG. 11 and described below.

Initially, at block 32 method 30 comprises receiving a digital image (e.g., a 3D digital image) of rock from a subterranean formation. For instance, the digital image may comprise a digital image generated from a natural or synthetic rock sample, or other porous media. The rock sample (e.g., a natural rock sample) may comprise a rock sample from a subterranean formation of interest.

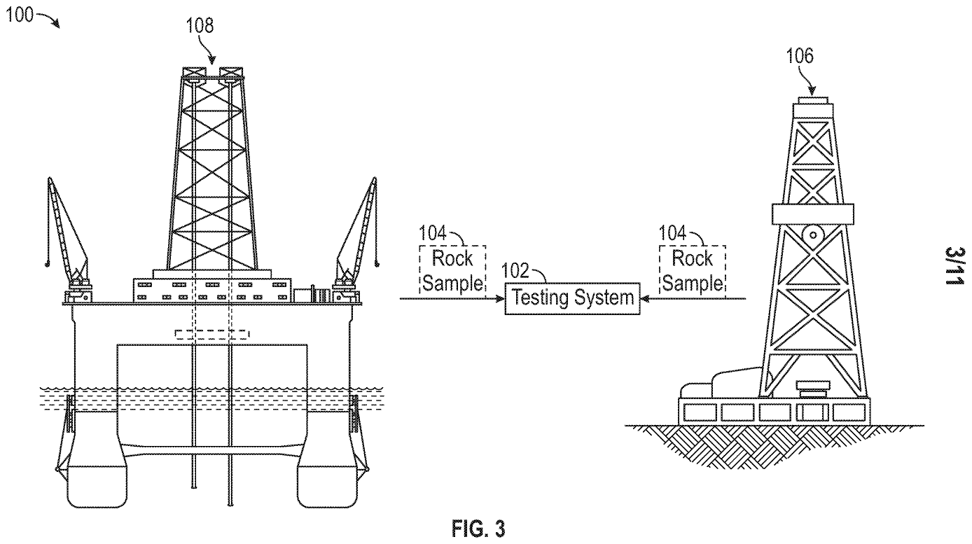

To provide an example, and referring to FIG. 3, a system 100 for acquiring and analyzing rock samples 104 for purposes of generating digital images of rock samples (e.g., the digital image received in block 32 of method 30 in FIG. 2) is shown according to some embodiments. In some embodiments, system 100 may be used to analyze rock samples 104 that are obtained from a subterranean formation for purposes of enhancing or facilitating oil and gas production from the subterranean formation. For example, in some embodiments rock samples 104 can be obtained from terrestrial drilling system 106 or from marine (ocean, sea, lake, etc.) drilling system 108, either of which is utilized to extract resources such as hydrocarbons (oil, natural gas, etc.), water, and the like.

The way rock samples 104 are obtained and the physical form of those samples can vary widely. Examples of rock samples 104 useful in connection with embodiments disclosed herein include whole core samples, sidewall core samples (e.g., obtained from the sidewall of a wellbore extending through the subterranean formation), outcrop samples, drill cuttings, and laboratory generated synthetic rock samples such as sand packs and cemented packs.

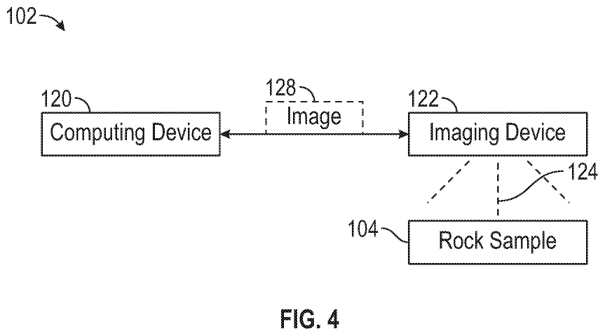

A testing system 102 of system 100 is configured to acquire and analyze 3D digital images 128 (shown in FIG. 4) of rock samples 104 to determine the physical properties of the corresponding sub-surface rock. The physical properties include, for example, petrophysical properties such as those petrophysical properties that are analyzed in the context of oil and gas exploration and production.

Referring to FIG. 4, a schematic diagram of testing system 102 is shown according to some embodiments. Testing system 102 includes imaging device 122 for obtaining 2D or 3D images, as well as other representations, of rock samples 104, such images and representations including details of the internal structure of the rock samples 104. An example of imaging device 122 is an X-ray CT scanner (or more simply “CT scanner”), which emits X-ray radiation 124 that interacts with an object and measures the attenuation of that X-ray radiation 124 by the object to generate an image of its interior structure and constituents. The type, construction, or other attributes of imaging device 122 can correspond to that of any type of X-ray device, such as a micro-CT scanner, capable of producing an image representative of the internal structure of rock sample 104. Other embodiments of imaging device 122 may utilize other imaging techniques, such as, X-ray nano-tomography, focused ion beam scanning electron microscopy, nuclear magnetic resonance, etc.

In some embodiments, the digital image volume may be computationally generated rather than produced by scanning the rock samples 104. In embodiments in which the digital image volume is produced by scanning a rock sample 104, the rock sample 104 may be a naturally occurring rock or a man-made porous material (e.g., a synthetic rock or other porous media).

3D digital image 128 may be composed of grayscale values representative of the attenuation of the X-ray radiation by the constituents of rock sample 104. In addition, 3D digital image 128 may comprise multiple two-dimensional (2D) slice images stacked along an axis of the rock sample 104, which together form the 3D digital image 128 of rock sample 104. In general, the stacking of the 2D slice images into 3D digital image 128 may be performed by computational resources of imaging device 122 itself, or by a separate computing device 120 from the series of 2D slice images produced by imaging device 122, depending on the architecture of testing system 102. Computing device 120 may comprise or be like the computer system 400 shown in FIG. 11.

The images produced by imaging device 122 may be partitioned into 3D regular elements called volume elements, or more commonly “voxels”. For example, each voxel may be cubic, having a side of equal length in the orthogonal X, Y, and Z directions. In some embodiments, the images produced by the imaging device 122 may be partitioned into non-cubic grid volume elements having varying geometries. The 3D digital image 128 itself may contain different numbers of voxels in the X, Y, and Z directions. Each voxel within a respective 3D digital image has an associated numeric value, or amplitude, that represents the relative material properties of the imaged sample at that location of the medium represented by the digital volume. The range of these numeric values (commonly known as the grayscale range) depends on the type of digital volume, the granularity of the values, the size of the data register (e.g., 8-bit or 16-bit values), and the like. For example, 16-bit data values enable the voxels of an X-ray tomographic image volume to have amplitudes ranging from 0 to 65,536 with a granularity of 1. In some embodiments, testing system 102 may perform image enhancement techniques (e.g., data smoothing, noise reduction) on the 3D digital image. Likewise, other components of testing system 102 (e.g., imaging device 122 itself) may alternatively perform image enhancement in whole or in part. The 3D digital images 128 captured by the imaging device 122 may comprise the digital images received at block 32 of method 30.

Referring again to FIG. 2, method 30 includes, at block 34, segmenting the digital image to estimate pore space and solid phase space in the rock sample using the digital image (e.g., the digital image obtained at block 32). In some embodiments, the testing system 102 shown in FIG. 3 performs segmentation or other image enhancement techniques on digital image 128 of rock sample 104 to distinguish and label different components or phases of digital image 128 shown in FIG. 4 based on the grayscale values of digital image 128. More specifically, computing device 120 may perform segmentation to identify components, such as pore space and solid phase space (e.g., space comprising mineralogical components) in the digital image 128. The resulting 3D digital image may comprise various solid material components labeled (for example, by mineral type) and the pore-space or void space labeled. In this exemplary embodiment, segmentation associates the voxels in the digital image with a particular material (or pore space, as the case may be) at the corresponding physical location within rock sample 104. Some or all of the voxels may be labeled with one or more material properties corresponding to the material constituent assigned to that voxel. For instance, such constituents may include void pore space, solid material space, clay fraction, individual grains, grain contacts, mineral types, and the like.

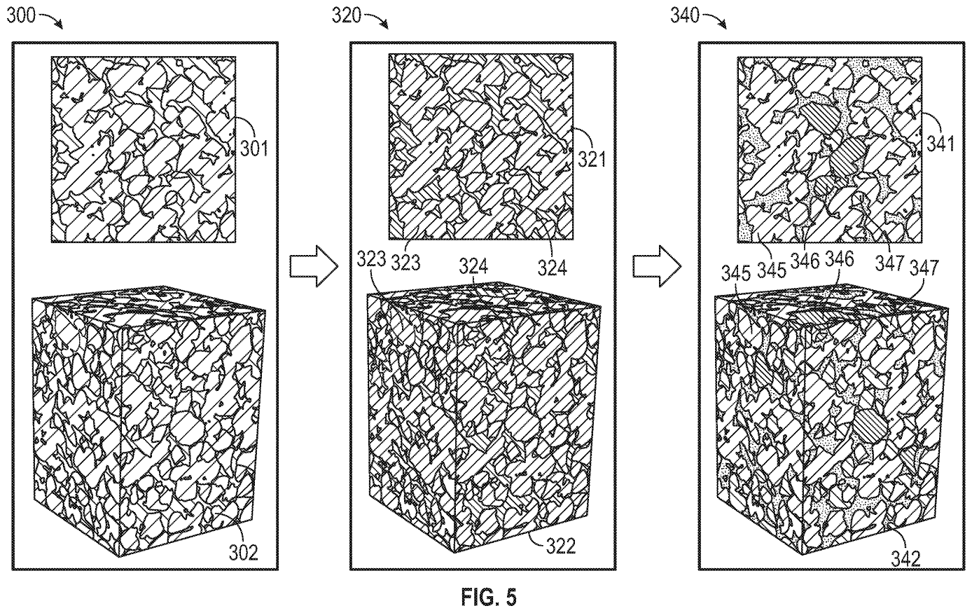

Referring to FIG. 5, exemplary views of digital image 128 of the rock sample 104 are shown. Particularly, FIG. 5 illustrates 2D slices 301, 320, 340 obtained from associated 3D views 302, 322, 342 of the digital image 128. The 2D slice 301, and its associated 3D view 302 of the digital image 128, illustrates a cross-sectional slice of the structural details of rock sample 104, where the grayscale value is indicative of the X-ray attenuation of that voxel as attained by testing system 102. In some embodiments, computing device 120 (or another computing device or devices) may perform this segmentation to identify components, such as pore space and mineralogical components (e.g., sandstone, clays and quartz). In some embodiments as represented in FIG. 5, the digital image 128 is segmented resulting in 2D slice 320, and associated 3D view 322 of the digital image, where each voxel is labeled as one, two or more significant phases, representing such material constituents as solid material 323 or pore space 324.

Computing device 120 of FIG. 4 may utilize any of a number of types of segmentation techniques to segment image 128. One approach to segmentation is the application of a “thresholding” process to image 128, in which computing device 120 chooses a threshold value within the voxel amplitude range. Those voxels having an amplitude below the threshold value are assigned one specific numeric value that denotes pore space, while those voxels having an amplitude above the threshold are assigned another numeric value that denotes matrix space (i.e., solid material). In this approach, thresholding converts a grayscale image volume to a segmented volume of voxels having different numeric values for example, 0, 1, 2 etc., depending on the number of labeled components.

Computing device 120 may utilize other segmentation techniques. For instance, in some embodiments computing device 120 may utilize Otsu's Method in which a histogram-based thresholding technique selects a threshold to minimize the combined variance of the lobes of a bimodal distribution of grayscale values (i.e., the “intra-class variance”). Otsu's method can be readily automated and extended to repeatedly threshold the image multiple times to distinguish additional material components such as quartz, clay, and feldspar. Other examples of automated segmentation techniques of varying complexity may alternatively or additionally be used by computing device 120 to distinguish different features of an image volume, such techniques including Indicator Kriging, Converging Active Contours, Watershedding, and the like.

In some embodiments and referring particularly to 2D slice 341 and associated 3D view 342 of image 128 shown in FIG. 5, the computing device 120 may further partition the identified phases of the segmented digital image to further distinguish the solid components of image 128. Particularly, further segmentation may be applied one or more times to differentiate various features within the image to distinguish between different materials such as clay, quartz, feldspar, etc. based on different X-ray attenuation characteristics, chemical signatures from a scanning electron microscope, or other distinguishing features.

As an example, partitioning can be performed using any imaging software (e.g., Avizo™ Software available from ThermoFisher Scientific™ of Hillsboro, Oreg., USA). During partitioning, a group of voxels can be identified as a grain. That is, each voxel or group of voxels define or represent a single grain, and various grains may be represented by different colored (or pattern, shades of grey) voxel or group of voxels as associated to a phase as shown particularly in 2D slice 341 and 3D view 342 (e.g., phases 345, 346, and 347). Specifically, 2D slice 341 and 3D view 342 of digital image 128 illustrate an example of a partitioned image of rock sample 104 including structural details of rock sample 104. The size (e.g., area, volume, radius, etc.) of each grain may be determined via imaging software.

The resultant mineral-mapped digital image 340 is a 3D digital image in which each voxel is labeled by a value that corresponds either to pore-space or solid phase/a specific phase associated with a specific solid phase mineral (e.g., calcite, K-feldspar, quartz, anorthite, pyrite) depending on the geology of rock sample 104. In some embodiments, each voxel may be assigned an integer that can be mapped to a particular solid phase mineral or to pore-space. Specific solid phase minerals may correspond to multiple values in 3D view 342. In other embodiments, such mineral-mapping exhibited in the digital image 340 may be not implemented by method 30 shown in FIG. 2 and instead each voxel of a selected 3D digital image may be mapped simply as pore space or solid material.

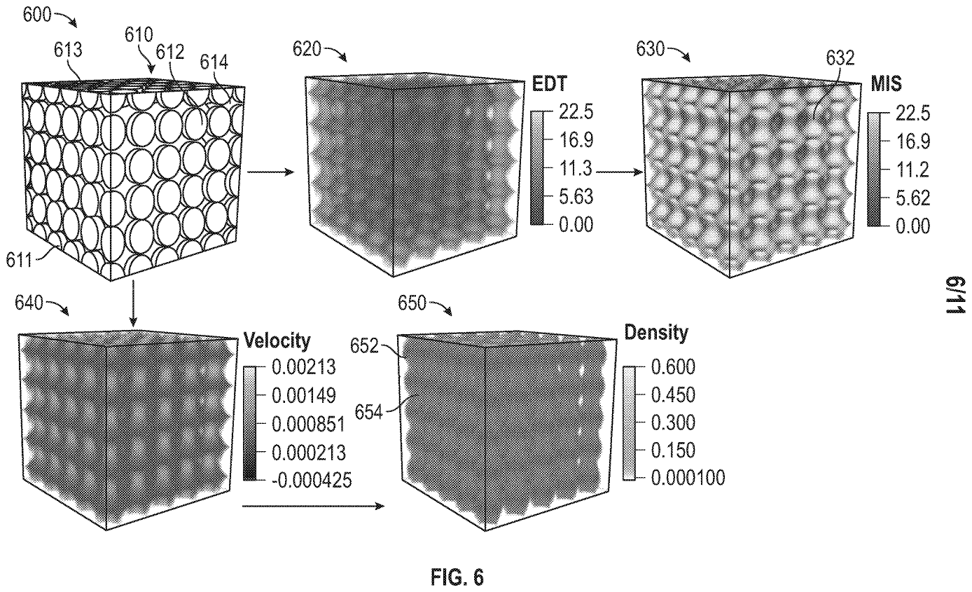

Referring back to FIG. 2, following block 34, the digital image has been divided into a plurality of voxels each labeled as either pore space or solid material. Proceeding to block 36, method 30 includes applying a geometric transform to the digital image to identify one or more features within the digital image. As previously described, geometric analysis may be applied to the segmented 3D image from which the size, and connectivity of the pores in the 3D image may be estimated. Referring to FIG. 6, an exemplary process 600 illustrating blocks 36, 38, 40 and 42 of method 30 is shown with respect to an exemplary 3D digital image volume 610.

In this example, the porous medium represented in the image volume 610 comprises a sphere pack of a plurality of equally sized solid spheres 612 (only one of which is labeled in FIG. 6 for clarity) packed together with voids or pore spaces 614 (only one of which is labeled in FIG. 6 for clarity) formed between the different solid spheres 612. Of course, the configuration of the porous medium represented in the image volume 610 may vary from the simplistic configuration shown in FIG. 6 in other embodiments. In this exemplary embodiment, a geometric transform is applied to the image volume 610 to initially identify and map the pore throats based on the image volume 610.

In this exemplary embodiment, an EDT image volume 620 is generated from the digital image by the application of the geometric transform thereto to map the pore spaces 614 in the image volume 610. As previously described, an EDT image of a 3D tomographic image is a map indicating, at each point in the pore space, how far that point is from the nearest “solid” or rock boundary using the shortest straight-line or Euclidean distance. Each voxel of the EDT image is assigned a number describing how deep the voxel is within a given pore where areas with higher numbers are further from solid boundaries indicating wider pore spaces. In some embodiments, EDT is applied to a binary representation of the image volume 610 for more efficient computation of the Euclidean distances. For instance, the pore spaces 614 mapped from the image volume 610 may be represented on a grid as a distinct element (e.g., represented with a value of 1) from the surrounding solid phase in the image volume 610 represented as a different element on the grid (e.g., represented with a value of 0), allowing the EDT algorithm to compute the shortest distance from the pore space to the solid boundaries. Alternatively, other geometric models besides Euclidean may be used to transform the image volume 610.

Referring back to FIG. 2, at block 38, method 30 includes generating a geometric model characterizing the structure of the one or more features identified at block 36. In this exemplary embodiment, following the generation of EDT image volume 620 by applying a geometric transform, a geometric model of the original image volume 610 quantifying the pore distribution (e.g., distribution of pore spaces 614) estimated from the original image volume 610 may be obtained from the EDT image. For example, an MIS model or image that identifies the best places within the image volume to “fit” the largest possible spheres inside the pores thereof to estimate the size of the corresponding pores may be applied. Referring again to FIG. 6, in this exemplary embodiment, a geometric model 630 in the form of an MIS image volume is generated based on the EDT image volume 620 generated at block 36. In this instance, local maximums are identified in the EDT image volume 620 where the distance to the solid boundary is greater than in surrounding areas and such local maximums may act as centers for the inscribed spheres of the geometric model 630. For example, each sphere 632 (only one of which is labeled in FIG. 6 for clarity) of the geometric model 630 is centered at a local maximum having a radius equal to the Euclidian distance at that location. Spheres 632 correspond to the largest sphere that may fit within the given pore space 614 without crossing the nearest solid boundary (e.g., defined by the nearest sphere 612). The size and distribution of these maximum inscribed spheres directly correlate with the pore throat sizes in the image volume 610.

Referring briefly again to FIG. 2, at block 40, method 30 includes determining a flow field of the digital image. Referring to FIG. 6, an exemplary flow field 640 is determined from the image volume 610 that models or represents the flow field extending therethrough. In some embodiments, determining the flow field for a porous medium (e.g., the sphere pack represented in image volume 610) comprises calculating a distribution of pressure and fluid flow velocity (e.g., under steady state conditions) within the porous medium at a particular time stamp (e.g., an initial time stamp or a subsequent time stamp). In some embodiments, the distribution of pressure and fluid flow velocity may be computed using a LB based steady-state solution. However, the flow field may be determined from a variety of different methods (e.g., numerical methods, optical flow methods, and physics-based neural networks) in other embodiments. The LB method is a temporally and spatially discrete solution to the Boltzmann equation that describes fluid flow and can fully recover the Navier-Stokes characterization of fluid behavior at the continuum scale. During this analysis, the fluid is modeled as a collection of discrete particles moving through a discretized regular lattice (e.g., representing the sphere pack of image volume 610). The fluid may be represented in terms of the probability of finding average populations of particles at a given time and position, with a certain velocity. The fluid particle movement through the lattice may be defined by a two-stage process occurring at each time step: streaming and collision.

The streaming stage refers to the advection of the particle to its next location and the collision stage represents the interaction of the particle with other particles occupying this new location. Generally, the particles are limited to movement along a finite number of directions and the particle velocities are restricted to a specific number of discrete values. Both the model dimensions and the number of directions the particle may be allowed to move determine the type of the given lattice that may be used to determine the flow field. In some embodiments, method 30 is performed for a 3D representation (e.g., a 3D digital representation or image) at least partially defined by porous media. Thus, as alluded to above, the flow field identified in block 40 may comprise a 3D flow field that accounts for the distribution of fluid velocity and/or pressure along three orthogonal directions (e.g., x, y, and z) within the 3D representation of at least a portion of the subterranean formation.

At block 42, method 30 includes simulating fluid flow through the pore spaces to identify one or more streamlines through the image volume. In some embodiments, the one or more streamlines extend entirely through the image volume such as continuously from a first endface of the image volume to an opposing second endface of the image volume. As used herein, the term “streamlines” is defined as the paths or directions that massless particles travel as they move with the flow of a fluid. These paths are tangent to the velocity vector of the fluid at any given point in space and time. Referring back to FIG. 6, streamline density model 650 models or represents an exemplary plot of streamline density (i.e., the number of streamlines passing through each voxel, normalized to the voxel with the maximum number of streamlines) illustrating a low streamline density region 652 (only one of which is labeled in FIG. 6 for clarity) and a higher streamline density region 654 (only one of which is labeled in FIG. 6 for clarity) through the image volume 610 along with their associated streamline densities.

The low streamline density region 652 of streamline density model 650 represent areas in the velocity field where the formation of individual flowpaths along which fluid particles are permitted to follow are sparse. These flowpaths are determined by the interconnected pore spaces 614 along which the fluid travels under the influence of pressure gradients. In other words, the distribution of streamlines is less dense in the low streamline density region 652, indicating reduced flow activity or less concentrated movement of fluid particles. Conversely, the high streamline density region 654 corresponds to areas where flowpaths are densely packed, signifying more active fluid movement and stronger velocity gradients. In this exemplary embodiment, each streamline extends continuously and entirely between a first endface 611 of image volume 610 and an opposing endface 613. In some embodiments, simulating fluid flow through interconnected pore spaces to identify one or more streamlines through the digital image includes tracing fluid particle movement though the pore network of the digital image in one or more directions, for example, tracing flowpaths of fluid particles from an inlet to an outlet of the digital image and from the outlet to the inlet, based on the computed velocity field to visualize the direction and behavior of the flow as it moves through the pore network of the digital image. In some embodiments, the velocity field may be generated using computational methods, typically by solving the flow equations (e.g., Navier-Stokes or lattice Boltzmann) within the pore network and identifying the trajectory of the streamline as fluid flows through the connected pores or void spaces by integrating or tracing the velocity field.

Additionally, the density of streamlines represented in streamline model 650, which represent how many streamlines pass through a given area within the pore space can be calculated and plotted across the digital image as shown in streamline model 650, to visualize the flow distribution across the digital image. In this instance, a higher density of streamlines in a region or area within the volume indicates higher flow activity or permeability. In other embodiments, the velocity of the fluid at each point and the flow rate across different regions or area within the digital image can also be plotted to visualize the flow distribution. By tracing the streamlines, regions of high and low flow efficiency, flow paths or passages, and restricting pore throats can be identified.

Referring back to FIG. 2, at block 44, method 30 includes determining a minimum diameter along the one or more streamlines based on the geometric model (e.g., geometric model 630 shown in FIG. 6) and the streamlines represented in the streamline model (e.g., streamline model 650 shown in FIG. 6). In an embodiment, the minimum diameter along one or more streamlines is determined by integrating or combining the MIS image volume with the identified streamlines. For example, the radius of the maximum inscribed sphere at each point or location along the streamlines may be calculated to generate a plurality of MIS radii for each of the one or more streamlines, from which the minimum of the MIS radii (i.e., smallest pore throat size along the streamline path) along each of the one or more streamlines can be determined. The minimum MIS diameter determined is the maximum size of a sphere that could be inscribed in that portion of the pore space within the digital image and thus represents the size of the smallest passageway or “throat” that connects larger pores within the porous media along a continuous flowpath extending through the porous media.

At block 46, method 30 includes generating a pore throat distribution of the image volume based on the minimum diameter along the one or more streamlines. In some embodiments, the distribution of pore throat sizes is generated based on statistical analysis. For example, a histogram or statistical plot of the pore throats may be generated from which the mean and standard deviation of the throat sizes, as well as probability distributions, can be determined from the minimum diameters along the one or more streamlines determined at block 44 to provide insights into the structure and morphology of the porous media. By integrating or combining the geometric model with the streamlines through the digital image, the size and distribution of the restricting pore throats for accurately predicting fluid and particle transport within the porous media is determined. The restricting pore throat size and thus, the natural ability of the formation rock to filter out certain sizes of particles around the wellbore allow engineers to optimize the completion design, including the size and design of filters, to ensure the filter captures particles that are not otherwise filtered out by the formation itself.

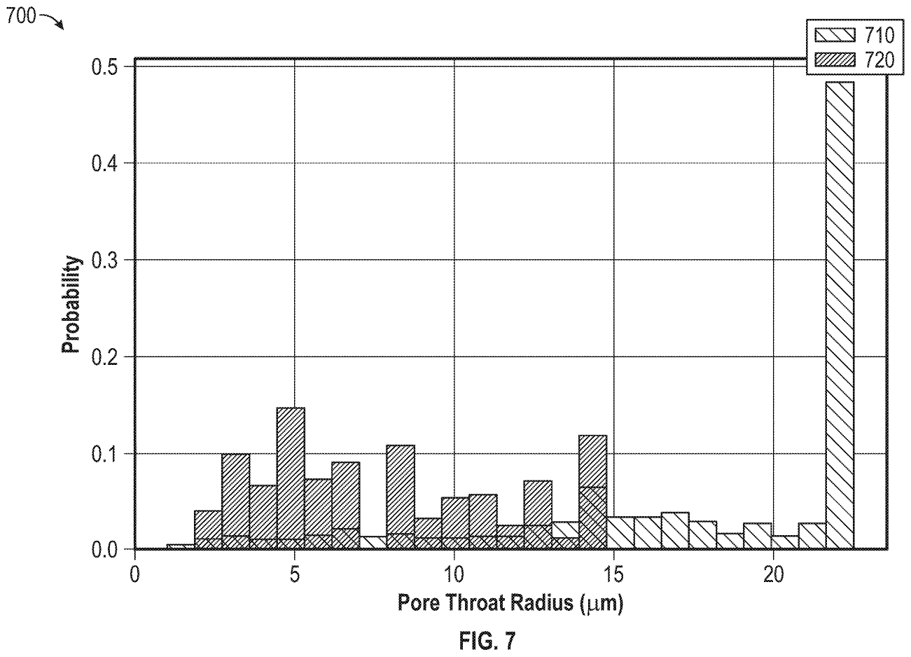

To illustrate the features of method 30 and referring to FIG. 7, a graphical representation illustrating an overlay of pore throat distribution for a porous media obtained by applying only a geometric analysis (e.g., based only on geometric model 630 and not integrating geometric model 630 with the streamline model 650) to the image volume of the porous media with pore throat distribution for the same porous media obtained by using method 30 (e.g., integrating the geometric model 630 with the streamline model 650) is shown. Particularly, FIG. 7 illustrates a graph 700 plotting a first pore throat distribution 710 generated from geometric analysis of the image volume 610 of FIG. 6 only (i.e., blocks 32, 34, 36, and 38 of FIG. 2) and a second pore throat distribution 720 of the image volume 610 generated from method 30 (i.e., combining the geometric model of the digital image with identified streamlines) as disclosed herein. Graph 700 plots pore throat radius in microns (μm) on the x-axis against frequency or probability (dimensionless) on the y-axis.

As can be observed in FIG. 7, graph 700 highlights substantial differences in how the pore throat distribution of the same porous media is characterized when using geometric analysis of the image of the porous media only versus integrating geometric analysis of the image of the porous media with streamlines through the digital image to generate the pore throat distribution. Particularly, plot 710 shows an exaggerated and unreasonably greater distribution of larger pore throats compared with plot 720 based on the wider range of pore throat radii; from about 1.5 to 23.5 μm for plot 710 versus from about 2.5 to 14.5 μm for plot 720. Additionally, a significant portion of the pore throat radii for plot 710 fall toward the larger pore throats based on probability of about 0.48 at 22-23 μm for plot 710 versus a probability of about 0.15 at 4-5.5 μm for plot 720.

As illustrated in graph 700 of FIG. 7, generating pore throat distribution based on geometric analysis of the digital image only may identify a broader range of larger pores with higher probability at larger sizes because unlike method 30, which integrates geometric analysis of the digital image with streamlines through the digital image, the geometric analysis of the digital image only approach does not capture or account for the restricting pore throat size a grain would encounter as it moves through the porous media along a flowpath extending continuously therethrough.

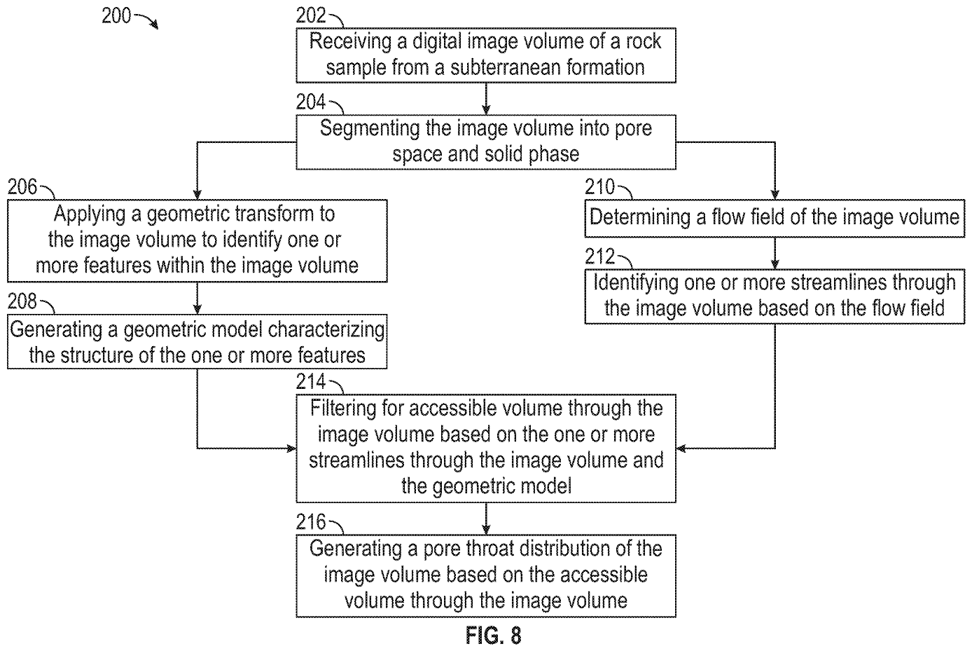

Referring to FIG. 8, another method 200 for estimating pore throat distribution in a porous media according to some embodiments is shown. At least some, if not all, of the steps or “blocks” of method 200 shown in FIG. 8 may be executed by the computer 400 shown in FIG. 11, although it is to be understood that at least some of the steps of method 200 may be executed by systems other than computer system 400. Additionally, and as discussed below, method 200 may incorporate at least some of the features or steps of method 30/process 600 described above and shown in FIGS. 2 and 6.

Beginning at block 202 method 200 includes receiving a digital image volume (e.g., a 3D digital image volume) of rock from a subterranean formation. As previously described, the image volume may comprise an image volume generated from a natural or synthetic rock sample, or other porous media. The rock sample may comprise a rock sample from a subterranean formation of interest in the form of whole core samples, sidewall core samples, outcrop samples, drill cuttings, etc. The rock sample is then imaged to generate a digital image (e.g., 3D digital image) volume of the porous media sample.

Method 200 includes, at block 204, segmenting the image volume (e.g., the image volume obtained at block 202) to estimate pore space and solid phase space in the rock sample using the image volume. As previously described, the testing system 102 shown in FIG. 3 may perform segmentation or other image enhancement techniques on image volume 128 of rock sample 104 to distinguish and label different components or phases of image volume 128 shown in FIG. 4 from the grayscale values of image volume 128. More specifically, computing device 120 may perform segmentation to identify components, such as pore space and solid phase space (e.g., space comprising mineralogical components) in image volume 128. The resulting image volume may comprise various solid material components labeled (for example, by mineral type) and the pore-space or void space labeled. In this exemplary embodiment, segmentation associates the voxels in the image volume with a particular material (or pore space, as the case may be) at the corresponding physical location within the rock sample. Some or all of the voxels may be labeled with one or more material properties corresponding to the material constituent assigned to that voxel. For instance, such constituents may include void pore space, solid material space, clay fraction, individual grains, grain contacts, mineral types, and the like.

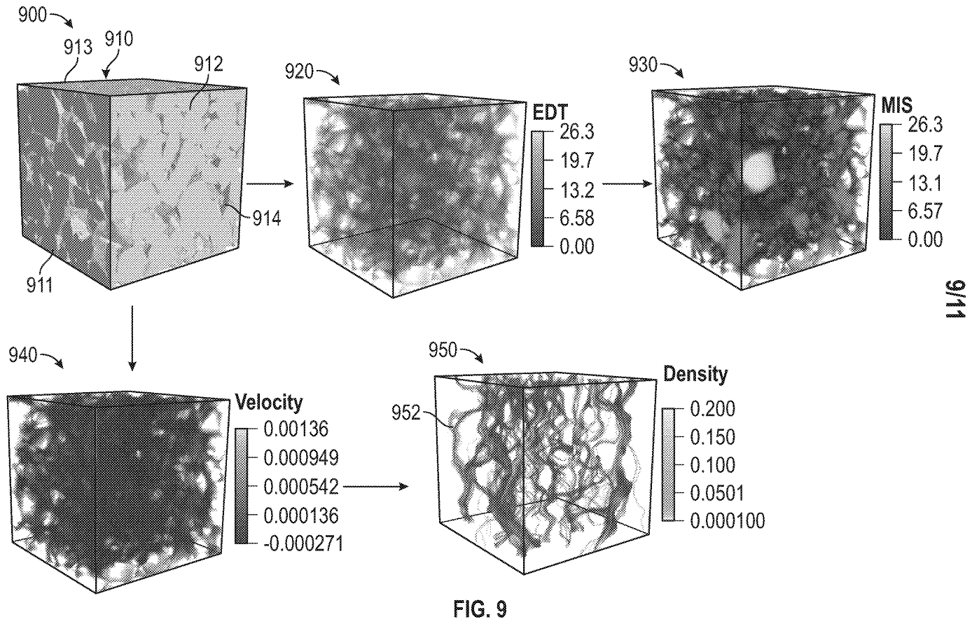

At block 206, method 200 includes applying a geometric transform to the image volume to identify one or more features within the image volume. Referring to FIG. 9, an exemplary process 900 illustrating blocks 206, 208, 210, and 212 of method 200 is shown. Process 900 begins with receiving a digital image volume 910 illustrating the solid rock 912 (e.g., as solid voxels) and the plurality of pore spaces 914 (e.g., as void space voxels) in the image volume 910. In this exemplary process, image volume 910 represents a volume of a sandstone comprising rock 912 and pore spaces 914. In this instance, the sandstone represented in image volume 910 approximates the complex irregular shapes of pores that may be formed in porous media.

Following receiving the image volume 910, a geometric transform is applied to map the pore spaces 914 contained within the image volume. In this exemplary embodiment, an EDT image volume 920 is generated to map the pore spaces 914 in the image volume 910. In this instance, the pore spaces 914 identified based on the image volume 910 are represented on a grid as a distinct element, and the surrounding solid phase in the image volume 910 is represented as a different element on the grid, allowing the EDT algorithm to compute the shortest distance from the pore space to the solid boundaries. Alternatively, other geometric models besides Euclidian distance may be used to transform the image volume 910.

Referring back to FIG. 8, at block 208, method 200 includes generating a geometric model characterizing the structure of the one or more features identified at block 206. In some embodiments, following the generation of a geometric image by applying a geometric transform, a geometric model of the original 3D image quantifying the pore distribution estimated from the 3D image may be obtained from the geometric image. For example, in certain embodiments, a geometric model or image that identifies specific features of the image volume (e.g., pores thereof to estimate the size of the corresponding pores) may be applied. Referring again to FIG. 9, in this example, a geometric model 930 in the form of a MIS image volume is generated based on the EDT image volume 920 generated at block 206. In some embodiments, local maximums may be identified in the EDT image volume 920 where the distance to the solid boundary is greater than in surrounding areas and such local maximums may act as centers for the inscribed spheres of the geometric model 930. For example, each sphere (not visible in geometric model 930) is centered at a local maximum having a radius equal to the Euclidian distance at that location. The spheres correspond to the largest sphere that may fit within the given pore without crossing the nearest solid boundary. The size and distribution of these maximum inscribed spheres directly correlate with the pore throat sizes in the image volume.

Referring back to FIG. 8, at block 210, method 200 includes determining a flow field of the image volume. Referring back to FIG. 9, volume 940 models or represents the flow field determined based on sandstone volume 910. As previously described, determining the flow field for a porous medium comprises calculating a distribution of pressure and fluid flow velocity within the porous medium at a particular time stamp. In some embodiments, the distribution of pressure and fluid flow velocity may be computed using a LB based steady-state solution as described above. Thus, as alluded to above, the flow field identified in block 206 may comprise a 3D flow field that accounts for the distribution of fluid velocity and/or pressure along three orthogonal directions (e.g., x, y, and z) within the 3D representation of at least a portion of the subterranean formation.

At block 212, method 200 includes identifying one or more streamlines through the image volume based on the flow field determined at block 210. Referring back to FIG. 9, volume 950 models or represents exemplary separate and distinct streamlines through the image volume, visualized as a streamline densities 952. Particularly, each of the streamlines comprising the streamline densities 952 extends entirely and continuously from a first endface 911 of the image volume 910 to an opposing second endface 913 of the image volume 910. Identifying one or more streamlines through the image volume may include tracing fluid particle movement though the pore network of the image volume in one or more directions based on the computed velocity field to visualize the direction and behavior of the flow as it moves through the pore network of the image volume.

In some embodiments, the flow field may be identified using computational methods, typically by solving the flow equations (e.g., Navier-Stokes or lattice Boltzmann) within the pore network and identifying the trajectory of the streamline as fluid flows through the connected pores or void spaces. In other embodiments, the velocity of the fluid at each point and the flow rate across different regions or area within the image volume can also be plotted to visualize the distributions. By tracing the streamlines, regions of high and low flow efficiency, flow paths or passages, and restricting pore throats can be identified.

Referring back to FIG. 8, at block 214, method 200 includes filtering for accessible volume through the image volume based on the one or more streamlines through the image volume and the geometric model. As used herein, “accessible volume” though the image volume refers to the total volume of the pore space within porous media that is connected and accessible to fluid flow. In other words, the accessible volume is the portion of the total pore volume that could be utilized for fluid flow within the porous media. In this exemplary embodiment, the accessible volume comprises pore space voxels that have at least one streamline connecting an inlet (e.g., first endface 911 of FIG. 9) to an outlet (e.g., second endface 913 of FIG. 9) of an image volume. In other words, pore space voxels through which no streamlines pass, or where fluid flow does not connect the inlet to the outlet, are excluded.

At block 216, method 200 includes generating a pore throat distribution based on the accessible volume through the image volume. In some embodiments, the distribution of pore throat sizes is generated based on statistical analysis of the integration of the geometric model with the streamline model. For example, a histogram or statistical plot of the pore throats may be generated from which the mean and standard deviation of the throat sizes, as well as probability distributions, can be determined to provide insights into the structure and morphology of the porous media. By integrating or combining the geometric model with the streamlines through the image volume, the size and distribution of the restricting pore throats for accurately predicting fluid and particle transport within the porous media is determined. The restricting pore throat size and thus, the natural ability of the formation rock to filter out certain sizes of particles around the wellbore, allow engineers to optimize the completion design, including the size and design of filters, to ensure the filter captures particles that are not, otherwise filtered out by the formation itself.

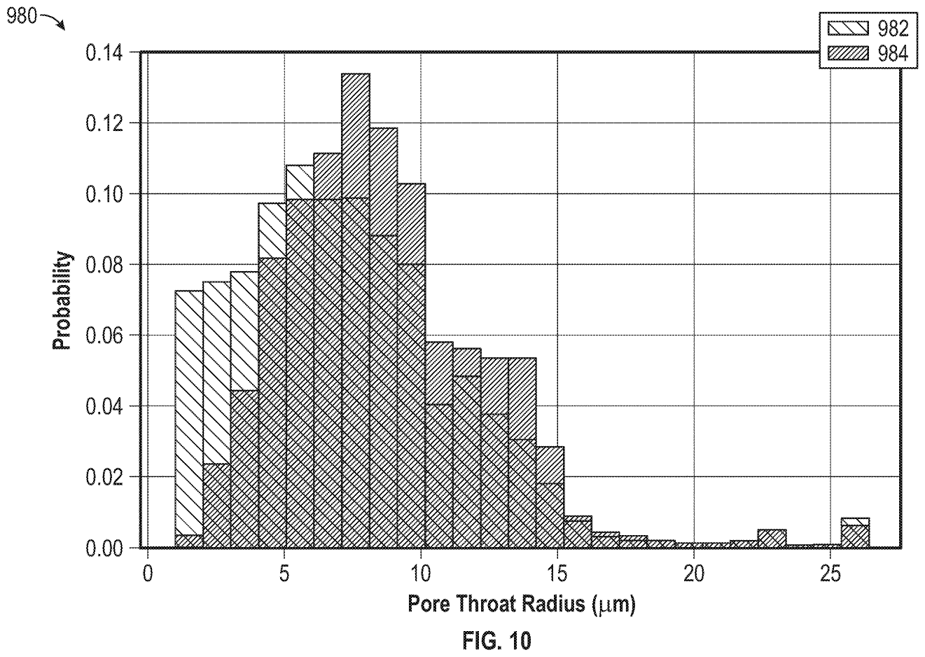

To illustrate the features of method 200 and referring to FIG. 10, a graphical representation illustrating overlay of pore throat distribution for a porous media obtained by using geometric analysis of the image volume only (i.e., blocks 202, 204, 206, and 208 of FIG. 8) with pore throat distribution for the same porous media obtained by using method 200 is shown. Particularly, FIG. 10 illustrates a graph 980 plotting a first pore throat distribution 982 generated from geometric analysis of the image volume only, and a second pore throat distribution 984 generated from method 200 (i.e., combining the geometric analysis of the image volume with identified streamlines) as disclosed herein. Graph 980 plots pore throat radius in microns (μm) on the x-axis against frequency or probability (dimensionless) on the y-axis.

As can be observed in FIG. 10, graph 980 highlights substantial differences in how the pore throat distribution of the same porous media is characterized based on accessible volume when using geometric analysis of the image volume of the porous media only versus integrating or combining geometric analysis of the image volume of the porous media with streamlines through the image volume to generate the pore throat distribution. Particularly, while plot 982 and plot 984 both show pore throat radii ranging from about 1 to 27 μm, the portion of the pore throat radii falling towards a majority of the pore throat sizes is less for plot 982 compared with the same pore throat radii for plot 984. For example, the probability of finding a pore throat radius of about 7 μm in plot 982 is about 0.10 versus about 0.13 in plot 984.

As illustrated in graph 980 of FIG. 10, generating pore throat distribution based on geometric analysis of the image volume only may not account for the connectivity and interconnectivity of the pores unlike method 200, which integrates geometric analysis of the image volume with streamlines through the image volume to determine pores that are part of a continuous and accessible flow path through the image volume.

Any of the systems and methods disclosed herein can be carried out (e.g., entirely or partially) on a computer or other device comprising a processor (e.g., a desktop computer, a laptop computer, a tablet, a server, a smartphone, a graphic processing unit (GPU) enabled device or some combination thereof). Referring now to FIG. 11, a computer system 400 suitable for implementing one or more embodiments disclosed herein is shown. The computer system 400 includes a processor 481 (which may comprise one or more central processor units (CPUs) and/or one or more GPUs) that is in communication with memory devices including secondary storage 482, read only memory (ROM) 483, random access memory (RAM) 484, input/output (I/O) devices 485, and network connectivity devices 486.

It is understood that by programming and/or loading executable instructions onto the computer system 400, at least one of the processors 481, the RAM 484, and the ROM 483 are changed, transforming the computer system 400 in part into a particular machine or apparatus having the novel functionality taught by the present disclosure. Thus, the RAM 484 and/or the ROM 483 may comprise a non-transitory machine-readable (or computer-readable) medium that may include instructions (which may be referred to herein as machine-readable instructions) that are executable by processor 481 to provide functionality to computer system 400. Thus, in some embodiments, a machine-readable instructions stored on a memory may be executed on a processor, to configured the processor to carry out some or all of the features of the methods described herein (e.g., method 30 shown in FIG. 2).

It is fundamental to the electrical engineering and software engineering arts that functionality that can be implemented by loading executable software into a computer can be converted to a hardware implementation by well-known design rules. Decisions between implementing a concept in software versus hardware typically hinge on considerations of stability of the design and numbers of units to be produced rather than any issues involved in translating from the software domain to the hardware domain. Generally, a design that is still subject to frequent change may be preferred to be implemented in software, because re-spinning a hardware implementation is more expensive than re-spinning a software design. Generally, a design that is stable that will be produced in large volume may be preferred to be implemented in hardware (for example in an application specific integrated circuit (ASIC), or field-programmable gate arrays (FPGA)) because for large production runs the hardware implementation may be less expensive than the software implementation. Often a design may be developed and tested in a software form and later transformed, by well-known design rules, to an equivalent hardware implementation in an application specific integrated circuit that hardwires the instructions of the software. In the same manner as a machine controlled by a new ASIC is a particular machine or apparatus, likewise a computer that has been programmed and/or loaded with executable instructions may be viewed as a particular machine or apparatus.

Additionally, after the system 400 is turned on or booted, the processor 481 may execute a computer program or application. For example, the processor 481 may execute software or firmware stored in ROM 483 or stored in RAM 484. In some cases, on boot and/or when the application is initiated, the processor 481 may copy the application or portions of the application from the secondary storage 482 to the RAM 484 or to memory space within the processor 481 itself, and the processor 481 may then execute instructions of which the application is comprised. In some cases, processor 481 may copy the application or portions of the application from memory accessed via the network connectivity devices 486 or via the I/O devices 485 to the RAM 484 or to memory space within the processor 481, and processor 481 may then execute instructions of which the application is comprised. During execution, an application may load instructions into processor 481, for example load some of the instructions of the application into a cache of processor 481. In some contexts, an application that is executed may be said to configure the processor 481 to do something, e.g., to configure the processor 481 to perform the function or functions promoted by the subject application. When processor 481 is configured in this way by the application, processor 481 becomes a specific purpose computer or a specific purpose machine.

The secondary storage 482 is typically comprised of one or more disk drives or tape drives and is used for non-volatile storage of data and as an over-flow data storage device if RAM 484 is not large enough to hold all working data. Secondary storage 482 may be used to store programs which are loaded into RAM 484 when such programs are selected for execution. The ROM 483 is used to store instructions and perhaps data which are read during program execution. ROM 483 is a non-volatile memory device which typically has a small memory capacity relative to the larger memory capacity of secondary storage 482. The RAM 484 is used to store volatile data and perhaps to store instructions. Access to both ROM 483 and RAM 484 is typically faster than to secondary storage 482. The secondary storage 482, the RAM 484, and/or the ROM 483 may be referred to in some contexts as computer readable storage media and/or non-transitory computer readable media.

I/O devices 485 may include printers, video monitors, electronic displays (e.g., liquid crystal displays (LCDs), plasma displays, organic light emitting diode displays (OLED), touch sensitive displays, etc.), keyboards, keypads, switches, dials, mice, track balls, voice recognizers, card readers, paper tape readers, or other well-known input devices.

The network connectivity devices 486 may take the form of modems, modem banks, Ethernet cards, Omni-Path Architecture (OPA), InfiniBand (IB), universal serial bus (USB) interface cards, serial interfaces, token ring cards, fiber distributed data interface (FDDI) cards, wireless local area network (WLAN) cards, radio transceiver cards that promote radio communications using protocols such as code division multiple access (CDMA), global system for mobile communications (GSM), long-term evolution (LTE), worldwide interoperability for microwave access (WiMAX), near field communications (NFC), radio frequency identity (RFID), and/or other air interface protocol radio transceiver cards, and other well-known network devices. These network connectivity devices 486 may enable the processor 481 to communicate with the Internet or one or more intranets. With such a network connection, it is contemplated that processor 481 might receive information from the network, or might output information to the network (e.g., to an event database) in the course of performing the methods described herein. Such information, which is often represented as a sequence of instructions to be executed using processor 481, may be received from and outputted to the network, for example, in the form of a computer data signal embodied in a carrier wave.

Such information, which may include data or instructions to be executed using processor 481 for example, may be received from and outputted to the network, for example, in the form of a computer data baseband signal or signal embodied in a carrier wave. The baseband signal or signal embedded in the carrier wave, or other types of signals currently used or hereafter developed, may be generated according to several known methods. The baseband signal and/or signal embedded in the carrier wave may be referred to in some contexts as a transitory signal.

Processor 481 executes instructions, codes, computer programs, scripts which it accesses from hard disk, floppy disk, optical disk, solid state drives (SSD) (these various disk-based systems may all be considered secondary storage 482), flash drive, ROM 483, RAM 484, or the network connectivity devices 486. While only one processor 481 is shown, multiple processors may be present. Thus, while instructions may be discussed as executed by a processor, the instructions may be executed simultaneously, serially, or otherwise executed by one or multiple processors. Instructions, codes, computer programs, scripts, and/or data that may be accessed from the secondary storage 482, for example, hard drives, floppy disks, optical disks, and/or other device, the ROM 483, and/or the RAM 484 may be referred to in some contexts as non-transitory instructions and/or non-transitory information.

In an embodiment, the computer system 400 may comprise two or more computers in communication with each other that collaborate to perform a task. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers. Further, the computer system 400 may comprise a graphics processing unit (GPU) for processing parallel tasks such as rendering graphics or performing complex computations efficiently. In an embodiment, virtualization software may be employed by the computer system 400 to provide the functionality of a number of servers that is not directly bound to the number of computers in the computer system 400. For example, virtualization software may provide twenty virtual servers on four physical computers. In an embodiment, the functionality disclosed above may be provided by executing the application and/or applications in a cloud computing environment. Cloud computing may comprise providing computing services via a network connection using dynamically scalable computing resources. Cloud computing may be supported, at least in part, by virtualization software. A cloud computing environment may be established by an enterprise and/or may be hired on an as-needed basis from a third-party provider. Some cloud computing environments may comprise cloud computing resources owned and operated by the enterprise as well as cloud computing resources hired and/or leased from a third-party provider.

In an embodiment, some or all of the functionality disclosed above may be provided as a computer program product. The computer program product may comprise one or more computer readable storage medium having computer usable program code embodied therein to implement the functionality disclosed above. The computer program product may comprise data structures, executable instructions, and other computer usable program code. The computer program product may be embodied in removable computer storage media and/or non-removable computer storage media. The removable computer readable storage medium may comprise, without limitation, a paper tape, a magnetic tape, magnetic disk, an optical disk, a solid-state memory chip, analog magnetic tape, compact disk read only memory (CD-ROM) disks, floppy disks, jump drives, digital cards, multimedia cards, and others. The computer program product may be suitable for loading, by the computer system 400, at least portions of the contents of the computer program product to the secondary storage 482, to ROM 483, to the RAM 484, and/or to other non-volatile memory and volatile memory of the computer system 400. The processor 481 may process the executable instructions and/or data structures in part by directly accessing the computer program product, for example by reading from a CD-ROM disk inserted into a disk drive peripheral of the computer system 400. Alternatively, processor 481 may process the executable instructions and/or data structures by remotely accessing the computer program product, for example by downloading the executable instructions and/or data structures from a remote server through the network connectivity devices 486. The computer program product may comprise instructions that promote the loading and/or copying of data, data structures, files, and/or executable instructions to the secondary storage 482, to the ROM 483, to the RAM 484, and/or to other non-volatile memory and volatile memory of the computer system 400.

In some contexts, the secondary storage 482, the ROM 483, and the RAM 484 may be referred to as a non-transitory computer readable medium or a computer readable storage media. A dynamic RAM embodiment of the RAM 484, likewise, may be referred to as a non-transitory computer readable medium in that while the dynamic RAM receives electrical power and is operated in accordance with its design, for example during a period of time during which the computer system 400 is turned on and operational, the dynamic RAM stores information that is written to it. Similarly, processor 481 may comprise an internal RAM, an internal ROM, a cache memory, and/or other internal non-transitory storage blocks, sections, or components that may be referred to in some contexts as non-transitory computer readable media or computer readable storage media.

The discussion above is directed to various exemplary embodiments. However, one of ordinary skill in the art will understand that the examples disclosed herein have broad application, and that the discussion of any embodiment is meant only to be exemplary of that embodiment and not intended to suggest that the scope of the disclosure, including the claims, is limited to that embodiment.

The drawing figures are not necessarily to scale. Certain features and components herein may be shown exaggerated in scale or in somewhat schematic form and some details of conventional elements may not be shown in interest of clarity and conciseness.

In the discussion above and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection of the two devices, or through an indirect connection that is established via other devices, components, nodes, and connections. In addition, when used herein (including in the claims), the words “about,” “generally,” “substantially,” “approximately,” and the like mean within a range of plus or minus 10%.

While exemplary embodiments have been shown and described, modifications thereof can be made by one skilled in the art without departing from the scope or teachings herein. The embodiments described herein are exemplary only and are not limiting. Many variations and modifications of the systems, apparatus, and processes described herein are possible and are within the scope of the disclosure. Accordingly, the scope of protection is not limited to the embodiments described herein, but is only limited by the claims that follow, the scope of which shall include all equivalents of the subject matter of the claims. Unless expressly stated otherwise, the steps in a method claim may be performed in any order. The recitation of identifiers such as (a), (b), (c) or (1), (2), (3) before steps in a method claim are not intended to and do not specify a particular order to the steps but rather are used to simplify subsequent reference to such steps.

What is claimed is:

1. A computer-implemented method for estimating pore throat distribution within a subterranean formation, the method comprising:
(a) receiving a digital image of a rock from the subterranean formation;
(b) segmenting the digital image into a plurality of voxels including a plurality of solid voxels each associated with a solid phase mineral of the subterranean formation and a plurality of void voxels each associated with a pore space of the subterranean formation;
(c) simulating fluid flow through the plurality of void voxels to identify one or more streamlines through a flowfield of the digital image;
(d) applying a geometric transform to the digital image to generate a geometric model of the digital image that maps pore space throughout the digital image; and
(e) integrating the one or more streamlines with the geometric model to identify a minimum pore size for each of the one or more streamlines.

2. The method of claim 1, further comprising:
(f) generating a pore throat distribution within the digital image based on the minimum pore size for each of the one or more streamlines.

3. The method of claim 1, wherein (d) comprises:
(d1) transforming the segmented digital image to generate an enhanced image identifying one or more features of the digital image.

4. The method of claim 3, wherein the one or more features of the digital image comprises a size and/or shape of pores and pore throats in the segmented digital image.

5. The method of claim 3, wherein (d) further comprises generating a distance map representing the solid voxels and void voxels by determining a distance from each void voxel to a nearest solid voxel in the digital image.

6. The method of claim 5, further comprising determining distances between the plurality of void voxels to generate the distance map.

7. The method of claim 1, wherein (c) comprises:
(c1) identifying the one or more streamlines through the digital image by tracing one or more flowpaths from an inlet to an outlet of the digital image and from the outlet to the inlet; and
(c2) determining a minimum diameter along each of the one or more flowpaths to obtain pore throat sizes in the digital image.

8. The method of claim 7, wherein the pore throat sizes comprise restricting pore throat sizes in the one or more flowpaths.

9. A computer-implemented method for estimating pore throat distribution within a subterranean formation, the method comprising:
(a) receiving a digital image of rock from the subterranean formation;
(b) segmenting the digital image into a plurality of voxels including a plurality of solid voxels each associated with a solid phase mineral of the subterranean formation and a plurality of void voxels each associated with a pore space of the subterranean formation;
(c) applying a geometric transform to the digital image to generate a geometric model of the digital image that identifies pore space distribution within the digital image;
(d) Identifying one or more streamlines through a flow field of the digital image;
(e) filtering for accessible volume through the digital image based on the one or more streamlines through the digital image and the geometric model; and
(f) generating a pore throat distribution within the digital image based on the accessible volume.

10. The method of claim 9, further comprising:
(g) integrating the one or more streamlines with the geometric model to identify a minimum pore throat size for each of the one or more streamlines.

11. The method of claim 9, wherein (c) comprises:
(c) transforming the segmented digital image to generate an enhanced image identifying one or more features of the digital image.

12. The method of claim 11, wherein the one or more features of the digital image comprises a size and/or shape of pores and pore throats in the segmented digital image.

13. The method of claim 11, wherein (c) further comprises generating a distance map representing the solid voxels and void voxels by determining a distance from each void voxel to a nearest solid voxel in the digital image.

14. The method of claim 13, further comprising determining distances between the plurality of void voxels to generate the distance map.

15. The method of claim 9, wherein (d) comprises:
(d1) identifying the one or more streamlines through the digital image by tracing one or more flowpaths from an inlet to an outlet of the digital image and from the outlet to the inlet; and
(d2) determining a minimum diameter along each of the one or more flowpaths to obtain pore throat sizes in the digital image.

16. A system for estimating pore throat distribution within a subterranean formation, the system comprising:
a processor; and
a memory coupled to the processor, wherein machine-readable instructions are stored in the memory, and wherein the machine-readable instructions, when executed on the processor, configure the processor to:
(a) receive a digital image of rock from the subterranean formation;
(b) segment the digital image into a plurality of voxels including a plurality of solid voxels each associated with a solid phase mineral of the subterranean formation and a plurality of void voxels each associated with a pore space of the subterranean formation;
(c) simulate fluid flow through the plurality of void voxels to identify one or more streamlines through a flow field of the digital image;
(d) apply a geometric transform to the digital image to generate a geometric model of the digital image that maps pore space throughout the digital image; and
(e) integrate the one or more streamlines with the geometric model to identify a minimum pore size for each of the one or more streamlines.

17. The system of claim 16, wherein the machine-readable instructions, when executed on the processor, further configure the processor to:
(f) generate a pore throat distribution of the digital image based on the minimum pore size for each of the one or more streamlines.

18. The system of claim 16, wherein the machine-readable instructions, when executed on the processor, further configure the processor to:
(d1) transform the segmented digital image to generate an enhanced image identifying one or more features of the digital image.

19. The system of claim 18, wherein the one or more features of the digital image comprises a size and/or shape of pores and pore throats in the segmented digital image.

20. The system of claim 18, wherein the machine-readable instructions, when executed on the processor, further configure the processor to: (d) generate a distance map representing the solid voxels and void voxels by determining a distance from each void voxel to a nearest solid voxel in the digital image.

21. The system of claim 20, wherein the machine-readable instructions, when executed on the processor, further configure the processor to determine distances between the plurality of void voxels to generate the distance map.

22. The system of claim 16, wherein the machine-readable instructions, when executed on the processor, further configure the processor to:
(c1) identify the one or more streamlines through the digital image by tracing one or more flowpaths from an inlet to an outlet of the digital image and from the outlet to the inlet; and
(c2) determine a minimum diameter along each of the one or more flowpaths to obtain pore throat sizes in the digital image.
